(19) United States
(12) Patent Application Publication
(10) Pub. No.: US 2008/0181558 A1
(43) Pub. Date: Jul. 31, 2008

(54) Electronic and optical circuit integration through wafer bonding

(76) Inventors: Peter G. Hartwell, Palo Alto, CA (US); Raymond Beausoleil, Redmond, WA (US); R. Stanley Williams, Palo Alto, CA (US); Duncan Stewart, Palo Alto, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/701,314

(22) Filed: Jan. 31, 2007

(51) Int. Cl. G02B 6/12; H01L 21/30

(52) U.S. Cl. 385/14; 438/455; 257/E21.211

(57) ABSTRACT

One embodiment in accordance with the invention is an apparatus that can include an optical circuit wafer and an integrated circuit wafer. The optical circuit wafer and the integrated circuit wafer are bonded together by a wafer bonding process.

### CROSS-REFERENCE TO RELATED APPLICATIONS

The present patent application is related to co-pending U.S. Patent Application Number entitled “Chip Cooling Channels Formed In Wafer Bonding Gap” by Peter G. Hartwell et al., filed Jan. 31, 2007, Attorney Docket Number 200602753, which is incorporated herein by reference.

### BACKGROUND

It can be desirable to add optical circuits to electronic circuits. For example, optical circuits added to electronic circuits can replace many layers of interconnect to improve bandwidth, decrease multiplexing and repeating complexity, and greatly reduce power consumption on a chip. However, there are some disadvantages to adding optical circuits to electronic circuits.

For example, the electronic circuit elements tend toward standard silicon processing while the optical circuit elements tend to be compound semiconductors. It is pointed out that standard silicon processing and compound semiconductors processing are generally difficult to integrate together. As such, non-standard processing is typically employed with the electronic circuits in order to integrate optical circuits with the electronic circuits. However, non-standard processing can greatly increase the cost of the electronic circuits. Furthermore, the integrated process can involve time and costs for requalification of parts if either the optical or electronics circuits processing is changed to reflect advances in general processing techniques in the rest of the industry.

Therefore, it is desirable to address one or more of the above issues.

### BRIEF DESCRIPTION OF THE DRAWINGS

FIG. 1A is a cross section side view of two wafers before a wafer bonding process in accordance with various embodiments of the invention.

FIG. 1B is an exemplary cross section side view of an exemplary chip in accordance with various embodiments of the invention.

FIG. 2 is an exemplary perspective view of a chip (or apparatus) in accordance with various embodiments of the invention.

FIG. 3 is an exemplary plan view of a chip (or apparatus) in accordance with various embodiments of the invention.

FIG. 4 is an exemplary plan view of a chip (or apparatus) in accordance with various embodiments of the invention.

FIG. 5 is an exemplary top view of the exemplary chip (or apparatus) in accordance with various embodiments of the invention.

FIG. 6 is an exemplary perspective view of a chip (or apparatus) in accordance with various embodiments of the invention.

FIG. 7 is an exemplary perspective view of a chip (or apparatus) in accordance with various embodiments of the invention.

FIG. 8 is an exemplary perspective view of a chip (or apparatus) in accordance with various embodiments of the invention.

FIG. 9 is a flow diagram of an exemplary method in accordance with various embodiments of the invention.

### DETAILED DESCRIPTION

Reference will now be made in detail to various embodiments in accordance with the invention, examples of which are illustrated in the accompanying drawings. While the invention will be described in conjunction with various embodiments, it will be understood that these various embodiments are not intended to limit the invention. On the contrary, the invention is intended to cover alternatives, modifications and equivalents, which may be included within the scope of the invention as construed according to the Claims. Furthermore, in the following detailed description of various embodiments in accordance with the invention, numerous specific details are set forth in order to provide a thorough understanding of the invention. However, it will be evident to one of ordinary skill in the art that the invention may be practiced without these specific details. In other instances, well known methods, procedures, components, and circuits have not been described in detail as not to unnecessarily obscure aspects of the invention.

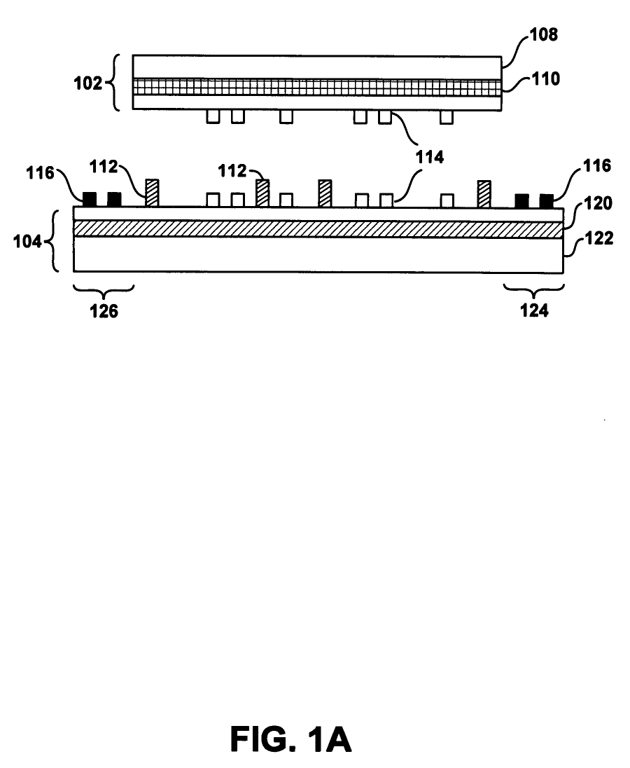

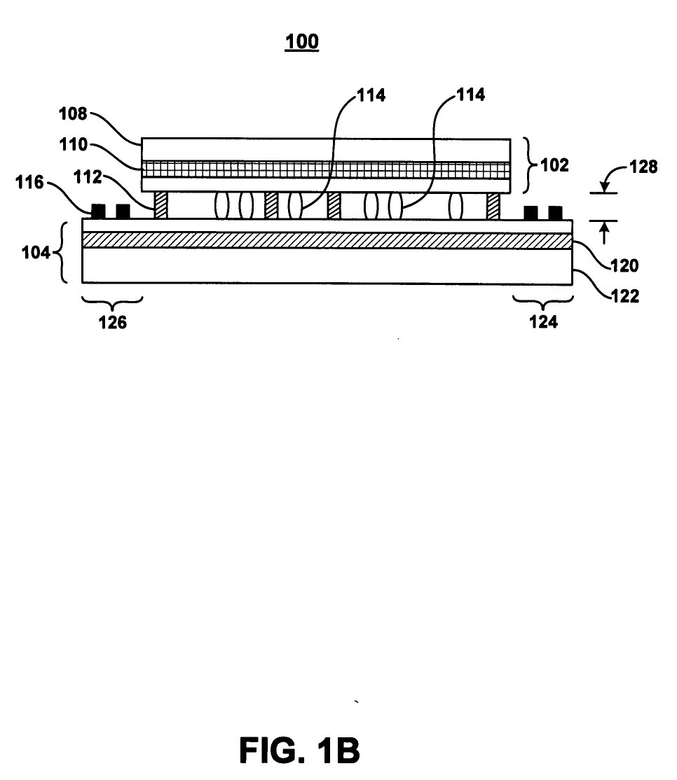

FIG. 1A is a cross section side view of two wafers before a wafer bonding process in accordance with various embodiments of the invention. Specifically, FIG. 1A illustrates an exemplary cap wafer 102 and an exemplary integrated circuit (IC) wafer 104 before a wafer bonding process. It is pointed out that one or more bonding materials 114 can be deposited or implemented on each of the cap wafer 102 and the integrated circuit wafer 104 in preparation for the wafer bonding process. Furthermore, one or more dielectric gap setting materials 112 can be deposited or implemented on the integrated circuit wafer 104 in preparation for the wafer bonding process. Specifically, during the wafer bonding process, one of the purposes of the one or more dielectric gap setting materials 112 can be to maintain and form a particular distance (or gap) between the cap wafer 102 and the integrated circuit wafer 104.

FIG. 1B is an exemplary cross section side view of an exemplary chip (or apparatus) 100 in accordance with various embodiments of the invention that provides electronic and optical circuit integration through wafer bonding. The chip 100 can include the optical circuit wafer 102 and the integrated circuit wafer 104, wherein the optical circuit wafer 102 and the integrated circuit wafer 104 are bonded together by a wafer bonding process. Note that the wafer bonding process can include, but is not limited to, eutectic bonding, compression bonding, fusion bonding, anodic bonding, plasma assisted bonding, and/or adhesive bonding. The integrated circuit wafer 104 can also be referred to as an electronic circuit wafer 104 or an electrical circuit wafer 104, but is not limited to such. In one embodiment, the wafer bonding process can include one or more bonds 114 that can couple the optical circuit wafer 102 and the integrated circuit wafer 104 while also providing electrical interconnects between the optical circuit wafer 102 and the integrated circuit wafer 104. It is pointed out that in one embodiment, the optical circuit wafer 102 can include one or more photodetectors, electronic optical modulators (EOMs), optical waveguides, laser, and/or electrical circuitry, but is not limited to such. In an embodiment, the integrated circuit wafer 104 can include one or more protrusions or “shelves” (e.g., 124 and 126) that project beyond the cap wafer 102, wherein the one or more protrusions can include one or more electrical bond pads 116 (e.g., for off-chip connections). In one embodiment, the integrated circuit wafer 104 can include one or more circuits 120, which can be electrical and/or optical, but is not limited to such. The one or more circuits 120 of the integrated circuit wafer 104 can include one or more active circuit elements, passive circuit elements, memory elements, programmable circuit elements, central processing units (CPUs), multi-core CPUs, field programmable gate arrays (FPGAs), and/or dynamic random access memories (DRAMs), but is not limited to such.

Within FIG. 1A, in one embodiment, the optical circuit wafer 102 and the integrated circuit wafer 104 can each be fabricated on a different wafer and then be brought together after each is complete by bonding them together. In this manner, chip 100 is an integrated system of electrical and optical circuits. For example in one embodiment, the integrated circuit wafer 104 can be fabricated in a standard process in a wafer fabrication facility and can be modified with a few additional operations in order to prepare it for a wafer bonding process. For instance, the operations can open additional vias in its top passivating layer and then a seed layer can be added that can form one half of the wafer bond in one embodiment. The bond material can include dielectric material 112 and/or wafer bonding interconnect material 114, but is not limited to such.

Within FIG. 1A, in one embodiment, the optical circuit wafer 102 can be fabricated with optical circuits, such as, electronic optical modulators, photodetectors, and/or optical waveguides, but is not limited to such. In an embodiment, the optical circuit wafer 102 can include a wafer 108 (e.g., silicon wafer) with deposited films for these devices or other substrate materials such as polymers. The optical circuit wafer 102 can contain a patterned layer that can form the bond to the integrated circuit wafer 102. It is noted that the bond material can be patterned to perform one or more functions, such as but not limited to, setting a gap 128 between the optical circuit wafer 102 and the integrated circuit wafer 104, forming areas to ensure good adhesion of the wafers 102 and 104, and/or making electrical interconnects to route signals to the optical circuit wafer 102 if it includes one or more additional devices or functionality.

It is noted out that the bond material of the wafer bonding process may be a conductor or an insulator or a combination of both, but is not limited to such. The wafer bonding method that can be utilized to couple the optical circuit wafer 102 and the integrated circuit wafer 104 can be implemented in a wide variety of ways. For example in various embodiments, the wafer bonding method can include, but is not limited to, silicon to oxide fusion bonding, silicon to oxide or oxide to oxide plasma assisted bonding, metal to oxide anodic bonding, metal to metal solder bonding, and metal to metal compression bonding. In one embodiment, a plasma assisted, solder, eutectic or compression bond may be used to prevent damage to integrated circuits of the integrated circuit wafer 104 from the high temperatures of the fusion bond or the high voltages in anodic bonding. Note that the solder, eutectic or compression bonds may include additional structures (e.g., 112) to help mechanically set the gap 128 between the optical circuit wafer 102 and the integrated circuit wafer 104. After bonding, in one embodiment, the optical wafer 102 can be patterned to allow access to electrical bonding pads 116 on the integrated circuit wafer 104, which can be used to route electrical signals to the pins of the IC package (not shown). Note that a scheme for this is presented in U.S. Pat. Nos. 7,042,105 and 6,955,976, which are incorporated herein by reference.

Within FIGS. 1A and 1B, in one embodiment, the stacked arrangement of the optical circuit wafer 102 and the integrated circuit wafer 104 can put the optical circuits directly above the electronic interconnects for the best performance. It is pointed out in an embodiment that each of the optical circuit wafer 102 and the integrated circuit wafer 104 can be individually tested before assembly to ease troubleshooting. In one embodiment, off-chip interconnect can be handled in a straightforward manner for both types of signals for the optical circuit wafer 102 and the integrated circuit wafer 104. In an embodiment, assembly or integration of the optical circuit wafer 102 and the integrated circuit wafer 104 can be straightforward using standard wafer bonding technology, but is not limited to such.

Within chip 100 of FIG. 1B, the integrated circuit wafer 104 (which can have electronic components) is located on the bottom and the optical circuit wafer 102 (which can have optical components) is located on top, but is not limited to such. In an embodiment, the optical circuit wafer 102 can be fabricated or processed using a compound semiconductor process to build its one or more electro-optical components, but is not limited to such. In one embodiment, the integrated circuit wafer 104 can be fabricated or processed in a CMOS (complementary metal-oxide-semiconductor) electronics process, but is not limited to such. It is noted that the optical circuit wafer 102 and the integrated circuit wafer 104 can be wafer bonded together with a physical and electrical interconnect, which can hold wafer 102 and 104 together and also allows electrical signals to go from the integrated circuit wafer 104 to the optical circuit wafer 102, and vice versa.

Note that the solder and eutectic wafer bonding methods can be implemented with low temperature (e.g., 250-350° C.). The bond material for each of these wafer bonding methods can include, but is not limited to, gold tin bond, gold germanium bond, and the like. For example, in the case of gold and tin bond, a gold layer can be deposited on a first wafer (e.g., 102) while a tin layer can be deposited on a second wafer (e.g., 104), then the wafers 102 and 104 can be adhered together. The gold and tin are heated up and then they inter-diffuse and bond wafers 102 and 104 together. In one embodiment, the bonding material can be deposited in a thin film manner, which can provide more precise control of the volume of bonding material. For solder and eutectic wafer bonding methods, the lead size or contact size can be approximately a 25 micron (or micrometer) circle, but is not limited to such. As previously mentioned, another wafer bonding technique can include compression bonding. For example, gold can be deposited on both the optical circuit wafer 102 and the integrated circuit wafer 104, then pressure and substantially no heat can be applied and the gold can intermingle and provide a bond coupling together wafers 102 and 104.

Within FIGS. 1A and 1B, it is noted that the one or more gap setting materials 112 may or may not be included within chip 100. In one embodiment, one or more gap setting materials 112 can be utilized during a compression wafer bonding process. In an embodiment, one or more gap setting materials 112 can be utilized during a solder or eutectic wafer bonding process in order to prevent the bonding material from being squeezed out from between the optical circuit wafer 102 and the integrated circuit wafer 104.

It is pointed out that one wafer bonding technique that can be utilized in accordance with an embodiment of the invention is called anodic bonding. Specifically, anodic bonding can involve bringing wafers 102 and 104 together and passing a current through wafer 102 and 104 to fuse them together. In one embodiment, it may be desirable with the anodic bonding to localize such so that the current does not pass through electronics of the integrated circuit wafer 104. Another wafer bonding technique that can be utilized in accordance with an embodiment of the invention is called fusion bonding, which can involve depositing silicon on one wafer (e.g., 102) and silicon dioxide on the other wafer (e.g., 104) and then bringing them together to form a bond. Yet another wafer bonding technique that can be utilized in accordance with an embodiment of the invention is called localized heating. For example in one embodiment, one or more lasers can be utilized to localize the heating, such as around the edge of the wafers 102 and 104, but is not limited to such.

Within FIG. 1B, the chip 100 can include the optical circuit wafer 102 and the integrated circuit wafer 104, which have been wafer bonded together. In one embodiment, the wafer bonding that coupled to the optical circuit wafer 102 and the integrated circuit wafer 104 can include wafer bonding interconnects 114. The optical circuit wafer 102 can include, but is not limited to, dielectric material, an optical substrate 108 (e.g., silicon), one or more optical circuits 110, and one or more metal interconnects. Furthermore, the optical circuit wafer 102 can be implemented to include gap setting material 112 (which can be referred to as a stand-off). The integrate circuit wafer 104 can include, but is not limited to, dielectric material, silicon wafer 122, one or more circuits 120 (e.g., optical and/or electronic), metal interconnects, one or more electrical bond pads 116, and one or more protrusions or “shelves” 124 and 126 that project beyond the cap wafer 102. Additionally, the cap wafer 102 and/or the integrated circuit wafer 104 can be implemented to include gap setting material 112.

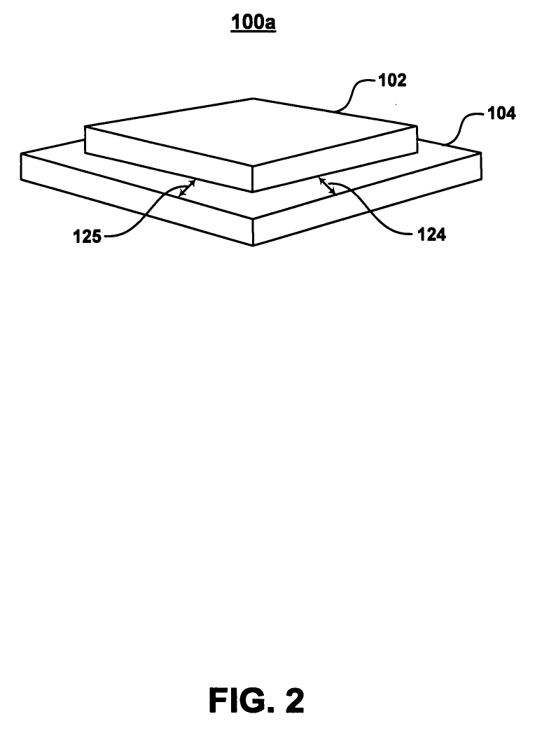

FIG. 2 is an exemplary perspective view of a chip (or apparatus) 100a in accordance with various embodiments of the invention. It is pointed out that FIG. 2 illustrates that the integrated circuit wafer 104 of the chip 100a can include one or more protrusions or “shelves” (e.g., 124 and 125) that project beyond the cap wafer 102. For example, one or more sides of the integrated circuit wafer 104 can project beyond one or more sides of the cap wafer 102. However, in one embodiment, it is noted that the integrated circuit wafer 104 of the chip 100a can be implemented without any protrusions or “shelves” (e.g., 124 and 125) that project beyond the cap wafer 102. As such, in this embodiment, the integrated circuit wafer 104 and the cap wafer 102 can be of substantially similar size, wherein their corresponding sides can be substantially flush.

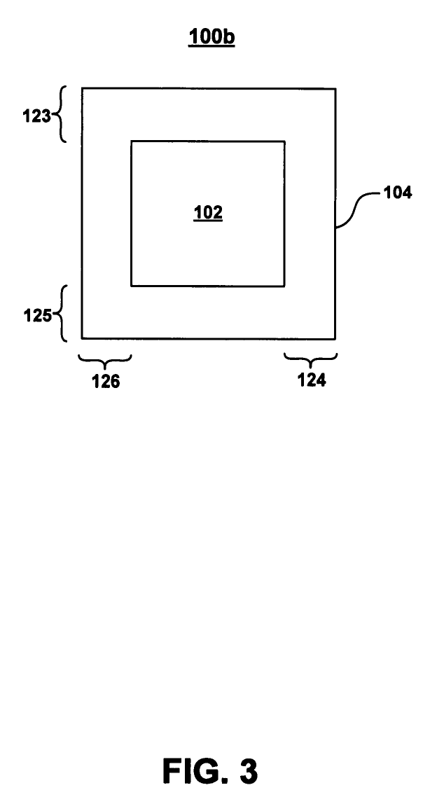

FIG. 3 is an exemplary plan view of a chip (or apparatus) 100b in accordance with various embodiments of the invention. Specifically, in one embodiment, the integrated circuit wafer 104 can include protrusions or “shelves” 123, 124, 125, and 126 on four of its sides that can project beyond the four sides of the cap wafer 102. However, in various embodiments, the integrated circuit wafer 104 can include one or more protrusions 123, 124, 125, and/or 126 that can project beyond the sides of the cap wafer 102. Note that one or more of the protrusions 123, 124, 125, and 126 can be implemented in a wide variety of ways. For example in one embodiment, each of protrusions 123, 124, 125, and 126 be implemented with electronic bond pads (e.g., 116), but is not limited to such. It is pointed out that each of the protrusions 123, 124, 125, and 126 can be implemented in any manner similar to that described herein, but is not limited to such.

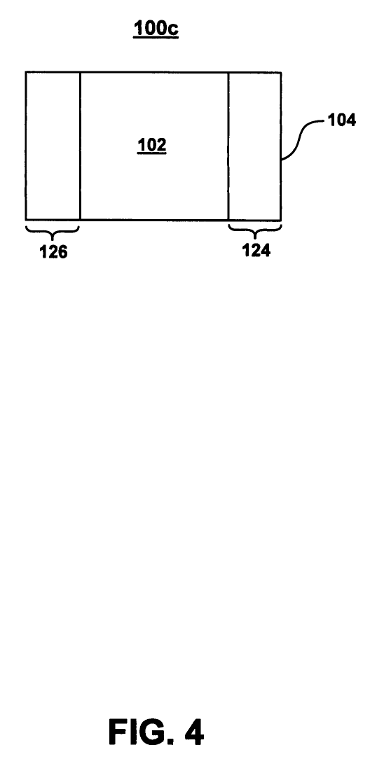

FIG. 4 is an exemplary plan view of a chip (or apparatus) 100c in accordance with various embodiments of the invention. Specifically, in one embodiment, the integrated circuit wafer 104 can include protrusions or “shelves” 124 and 126 on two of its sides that can project beyond the four sides of the cap wafer 102. It is pointed out that one or more of the protrusions 124 and 126 can be implemented in a wide variety of ways. It is noted that each of the protrusions 124 and 126 can be implemented in any manner similar to that described herein, but is not limited to such.

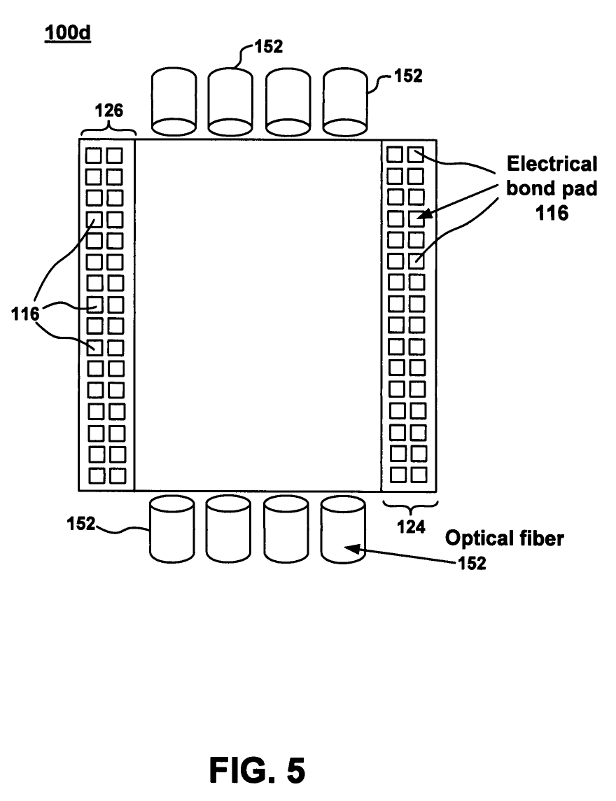

FIG. 5 is an exemplary top view of an exemplary chip (or apparatus) 100d in accordance with various embodiments of the invention. Note that chip 100d can be a top view of chip 100 of FIG. 1. Note that optical signals can be routed in via one or more optical fibers 152 from one or more sides of the chip 100d, which is a wafer stack that can include the optical circuit wafer 102 and the integrated circuit wafer 104. In order to facilitate the electrical and optical off-chip interface in one embodiment, one or more electronic bond pads 116 can implemented on each of the protrusion sides 124 and 126 of the wafer 104 of chip 100d, while the optical connections can be implemented on the two other sides of chip 100d, as shown in FIG. 5.

Specifically, the integrated circuit wafer 104 of the chip 100d can include protrusions 124 and 126, which can each include one or more electrical bond pads 116. In one embodiment, as shown in FIG. 5, protrusion 126 is located on one side of the integrated circuit wafer 104 while protrusion 124 can be located on the opposite side of the integrated circuit wafer 104. It is pointed out that protrusions 124 and 126 of FIG. 5 correspond to protrusion or “shelves” 124 and 126 of FIGS. 1 and 4. Note that a wire (e.g., approximately 25 microns in diameter) can electrically couple each electrical bond pad 116 to a package (not shown) for the chip 100d. By limiting the electrical pads 116 to two sides of the chip 100d, the chip 100d can have no overhang or be flush on its other two sides. In this manner, as shown in FIG. 5, one or more optical fibers 152 can be located right next to or abutted against one or more of the flush edges or sides of the chip 100d, thereby enabling improved optical transmission between them and the optical circuits (e.g., 110) of the optical circuit wafer 102.

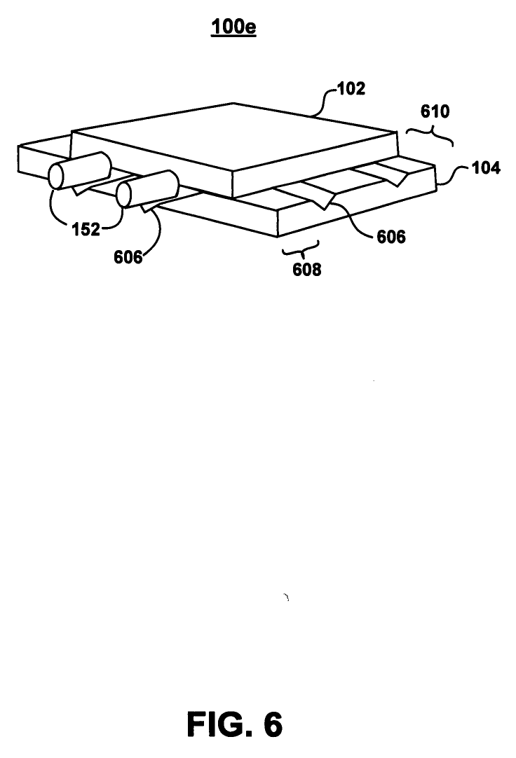

Within FIG. 5, the one or more optical fibers 152 can be implemented in a wide variety of ways. For example in one embodiment, the optical fibers 152 can each be approximately 125 microns in diameter, but is not limited to such. It is pointed out that the core of each optical fiber 152 can be aligned with the optical circuits (e.g., 110) of the optical circuit wafer 102 to provide proper optical transmission. In one embodiment, the optical circuits can be implemented to be a layer that is approximately 20 microns thick, but is not limited to such. The alignment of the optical fiber 152 can be implemented by the packaging for the chip 100d. For example in one embodiment, a “V” groove can be included as part of the package (e.g., as shown in FIG. 6) for chip 100d in order to align each optical fiber 152, wherein each optical fiber 152 can rest within its V-groove. In an embodiment, it is noted that one or more V-grooves can be fabricated into the integrated circuit wafer 104, wherein the optical fibers 152 can rest and be aligned with the optical circuits 110.

It is pointed out that chip 100d can be implemented in a wide variety of ways. For example in one embodiment, the integrated circuit wafer 104 can include a single protrusion or “shelf” for electrical interconnects (e.g., 116) on any of its sides while its three remaining sides can be used for optical interconnects (e.g., 152). In an embodiment, the integrated circuit wafer 104 can include three protrusion of “shelves” for electrical interconnects (e.g., 116) on any of its sides while the remaining side can be used for optical interconnects (e.g., 152).

FIG. 6 is an exemplary perspective view of a chip (or apparatus) 100e in accordance with various embodiments of the invention. Specifically, FIG. 6 illustrates that one or more grooves (or trenches or patterned features) 606 can be implemented within one or more protrusions or “shelves” 608 and 610 of the chip 100e in various embodiments. It is pointed out that grooves 606 can assist in the alignment of optical fibers 152 with any optical circuits (e.g., 110) of chip 100e. It is noted that the optical fibers 152 can be edge-coupled to the wafers 102 and/or 104 of the chip 100e.

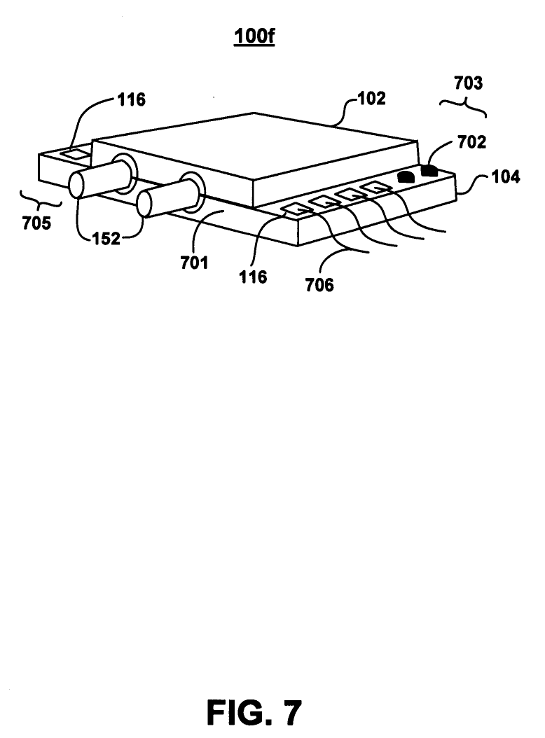

FIG. 7 is an exemplary perspective view of a chip (or apparatus) 100f in accordance with various embodiments of the invention. Specifically, FIG. 7 illustrates different off-chip connections that can be implemented with chip 100f in various embodiments. For example, the chip 100f can be implemented to include on its flush side 601 one or more optical fibers 152 for handling optical communication. In this manner, the optical fibers 152 can be edge-coupled to the wafers 102 and/or 104 of the chip 100f. Furthermore, a protrusion or “shelf” 703 of the chip 100f can be implemented to include one or more bond pads 116 along with one or more solder bumps 702 for a surface mount package. It is pointed out that wire 706 can be bonded to each of the bond pads 116. Moreover, a protrusion or “shelf” 705 of the chip 100f can be implemented to include one or more bond pads 116, but is not limited to such.

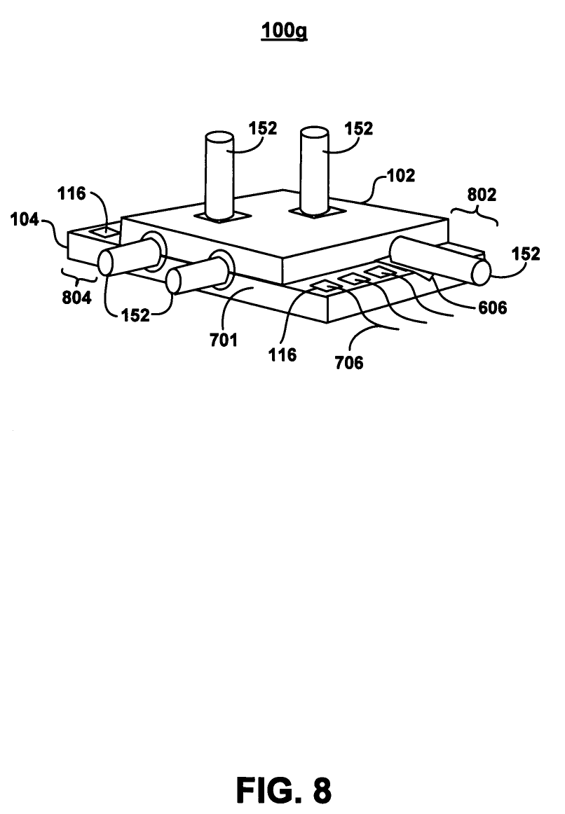

FIG. 8 is an exemplary perspective view of a chip (or apparatus) 100g in accordance with various embodiments of the invention. Specifically, FIG. 8 illustrates different off-chip connections that can be implemented with chip 100g in various embodiments. For example, the chip 100g can be implemented to include on its flush side 701 one or more optical fibers 152 for handling optical communication. Moreover, a protrusion or “shelf” 802 of the chip 100g can be implemented to include one or more bond pads 116 along with a groove 606 for assisting in the alignment of an optical fiber 152, which is end-coupled to wafers 102 and/or 104. It is pointed out that wire 706 can be bonded to each of the bond pads 116. Moreover, a protrusion or “shelf” 704 of the chip 100g can be implemented to include one or more bond pads 116, but is not limited to such. Additionally, one or more optical fibers 152 can be surface mounted substantially perpendicular to the wafer 102 of the chip 100g. The optical fibers (or fiber-optic connecters) 152 of the chip 100g can be utilized to transmit light onto and off of chip 100g. For example in one embodiment, the optical fibers (or fiber-optic connecters) 152 of the chip 100g can be utilized to transmit light onto and off of wafer 102. It is noted that surface mounted lasers can be utilized as light sources for the optical fibers 152.

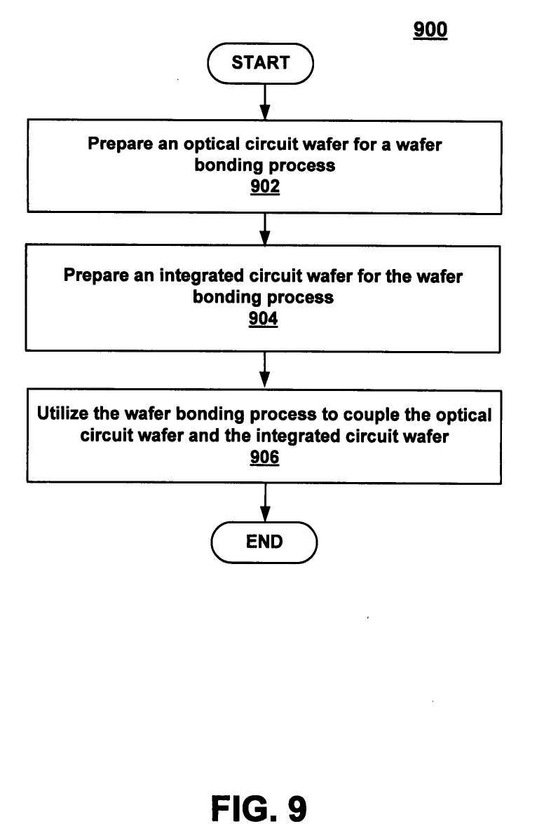

FIG. 9 is a flow diagram of an exemplary method 900 in accordance with various embodiments of the invention for electronic and optical circuit integration through wafer bonding. Method 900 includes exemplary processes of various embodiments of the invention that can be carried out by a processor(s) and electrical components under the control of computing device readable and executable instructions (or code), e.g., software. The computing device readable and executable instructions (or code) may reside, for example, in data storage features such as volatile memory, non-volatile memory, and/or mass data storage that can be usable by a computing device. However, the computing device readable and executable instructions (or code) may reside in any type of computing device readable medium. Note that method 900 can be implemented with application instructions on a computer-usable medium where the instructions when executed effect one or more operations of method 900. Although specific operations are disclosed in method 900, such operations are exemplary. Method 900 may not include all of the operations illustrated by FIG. 9. Also, method 900 may include various other operations and/or variations of the operations shown by FIG. 9. Likewise, the sequence of the operations of method 900 can be modified. It is noted that the operations of method 900 can be performed manually, by software, by firmware, by electronic hardware, or by any combination thereof.

Specifically, method 900 can include preparing an optical circuit wafer for a wafer bonding process. An integrated circuit wafer can be prepared for the wafer bonding process. The wafer bonding process can be utilized to couple the optical circuit wafer and the integrated circuit wafer. In this manner, electronic circuit and optical circuit integration can be accomplished through wafer bonding, in accordance with various embodiments of the invention.

At operation 902 of FIG. 9, an optical circuit wafer (e.g., 102) can be prepared for a wafer bonding process. It is noted that operation 902 can be implemented in a wide variety of ways. For example in one embodiment, the preparing of the optical circuit wafer at operation 902 can include depositing one or more patches of a thin film of material (e.g., metal, silicon dioxide, etc.) above the optical circuit wafer. In an embodiment, the preparing of the optical circuit wafer at operation 902 can include fabrication of the optical circuit wafer (e.g., in a manner similar to that described herein, but is not limited to such). In an embodiment, the optical circuit wafer can include a gap setting material (e.g., 112) for maintaining a distance or a gap (e.g., 128) between the optical circuit wafer and the electrical circuit wafer during the wafer bonding process. Operation 902 can be implemented in any manner similar to that described herein, but is not limited to such.

At operation 904, an integrated circuit wafer (e.g., 104) can be prepared for the wafer bonding process. It is pointed out that operation 904 can be implemented in a wide variety of ways. For example in one embodiment, the preparing of the integrated circuit wafer at operation 904 can include depositing one or more patches of a thin film of material (e.g., metal, silicon dioxide, etc.) above the integrated circuit wafer. In an embodiment, the preparing of the optical circuit wafer at operation 904 can include fabrication of the integrated circuit wafer (e.g., in a manner similar to that described herein, but is not limited to such). In an embodiment, the integrated circuit wafer can include a gap setting material (e.g., 112) for maintaining a distance or a gap (e.g., 128) between the optical circuit wafer and the integrated circuit wafer during the wafer bonding process. Operation 904 can be implemented in any manner similar to that described herein, but is not limited to such.

At operation 906 of FIG. 9, the wafer bonding process can be utilized to couple the optical circuit wafer and the integrated circuit wafer. Note that operation 906 can be implemented in a wide variety of ways. For example in one embodiment, the wafer bonding process can include one or more bonds that couple the optical circuit wafer and the integrated circuit wafer, wherein the one or more bonds are also electrical interconnects between the optical circuit wafer and the integrated circuit wafer. Operation 906 can be implemented in any manner similar to that described herein, but is not limited to such.

The foregoing descriptions of various specific embodiments in accordance with the invention have been presented for purposes of illustration and description. They are not intended to be exhaustive or to limit the invention to the precise forms disclosed, and obviously many modifications and variations are posisble in light of the above teaching. The invention can be construed according to the Claims and their equivalents.

What is claimed is:

1. An apparatus comprising:
an optical circuit wafer; and
an integrated circuit wafer, wherein said optical circuit wafer and said integrated circuit wafer are bonded together by a wafer bonding process.

2. The apparatus of claim 1, wherein said wafer bonding process is selected from the group consisting of eutectic bonding, compression bonding, fusion bonding, anodic bonding, plasma assisted bonding, and adhesive bonding.

3. The apparatus of claim 1, wherein a side of said integrated circuit wafer projects beyond said optical circuit wafer and comprises a bond pad configured for receiving an electrical coupling.

4. The apparatus of claim 1, wherein said wafer bonding process comprises an electrical interconnect between said optical circuit wafer and said integrated circuit wafer.

5. The apparatus of claim 4, wherein said electrical interconnect enables the integrated circuit wafer and the optical circuit wafer to exchange electrical signals.

6. The apparatus of claim 1, wherein said optical circuit wafer includes one or more elements selected from the group consisting of a photodetector, an electronic optical modulator, an optical waveguide, a laser, and electrical circuitry.

7. The apparatus of claim 1, wherein said integrated circuit wafer comprises a gap setting material for maintaining a distance between said optical circuit wafer and said integrated circuit wafer during said wafer bonding process.

8. The apparatus of claim 1, wherein a side of said apparatus is configured for receiving an external optical coupling to couple an optical signal to said optical circuit wafer.

9. The apparatus of claim 8, wherein said external optical coupling comprises a fiber-optic connector.

10. The apparatus of claim 1, wherein a surface of said optical wafer is configured for receiving an external optical coupling to couple an optical signal to said optical circuit wafer.

11. The apparatus of claim 1, wherein said integrated circuit wafer includes an element selected from the group consisting of an active circuit element, a passive circuit element, a memory element, and a programmable circuit element.

12. A method comprising:
utilizing a wafer bonding process to couple an optical circuit wafer and an integrated circuit wafer.

13. The method of claim 12, wherein said wafer bonding process is selected from the group consisting of eutectic bonding, compression bonding, fusion bonding, anodic bonding, plasma assisted bonding, and adhesive bonding.

14. The method of claim 12, wherein said wafer bonding process comprises a bond that is an electrical interconnect between said optical circuit wafer and said integrated circuit wafer.

15. The method of claim 12, wherein a side of said integrated circuit wafer projects beyond said optical circuit wafer and comprises an electrical bond pad for receiving an electrical coupling external to said integrated circuit wafer and said optical circuit wafer.

16. A method comprising:
preparing an optical circuit wafer for a wafer bonding process;
preparing an integrated circuit wafer for said wafer bonding process; and
utilizing said wafer bonding process to couple said optical circuit wafer and said integrated circuit wafer.

17. The method of claim 16, wherein said wafer bonding process comprises a bond that couples said optical circuit wafer and said integrated circuit wafer, said bond further comprises an electrical interconnect between said optical circuit wafer and said integrated circuit wafer.

18. The method of claim 16, wherein said preparing said optical circuit wafer comprises:
depositing a thin film of material above said optical circuit wafer.

19. The method of claim 16, wherein said preparing said integrated circuit wafer comprises:
depositing a thin film of metal above said integrated circuit wafer.

20. The method of claim 16, wherein said integrated circuit wafer comprises a gap setting material for maintaining a distance between said optical circuit wafer and said integrated circuit wafer during said wafer bonding process.
